(19) United States
(12) Patent Application Publication
(10) Pub. No.: US 2026/0136898 A1
(43) Pub. Date: May 14, 2026

(54) Method for Micro-Patterning Silicon Carbide Seed Wafer for Crystal Growth

(71) Applicant: LEAP Semiconductor Corp., Taoyuan City (TW)

(72) Inventors: Kai-Chi HSIAO, Taoyuan City (TW); Wen-Chung LI, Taoyuan City (TW)

(21) Appl. No.: 19/228,840

(22) Filed: Jun. 5, 2025

(30) Foreign Application Priority Data
Nov. 8, 2024 (TW) 113143060

(51) Int. Cl. H01L 21/02; C30B 23/02

(52) U.S. Cl. CPC H10P 90/15; C30B 23/025

(57) ABSTRACT

The present invention discloses a method for micro-patterning a silicon carbide seed wafer for crystal growth. The present invention facilitates control over the polytype for the following crystal growth, ensuring the resulting crystal corresponds to the desired silicon carbide polytype, preventing the formation of undesired polytypes.

### BACKGROUND OF THE INVENTION

### 1. Field of the Invention

The present invention relates to a method for micro-patterning a silicon carbide (SiC) seed wafer, and more particularly to a method for micro-patterning a surface of a silicon carbide (SiC) seed wafer for crystal growth.

### 2. Description of the Prior Art

Currently, the predominant method for growing silicon carbide (SiC) single crystals is physical vapor transport (PVT). Silicon carbide (SiC) is hardly grown in the liquid phase, therefore, silicon carbide (SiC) crystal growth must be achieved through sublimation in a high temperature environment. In both PVT crystal growth and epitaxial growth, the exposed c-axis stacking sequence is crucial for suppressing polytype formation by promoting step-flow growth. Both growth processes normally rely on an off-axis seed or substrate, which guides deposited species to align with the stacking sequence, to facilitate the preferential incorporation of adatoms along step edges, thereby stabilizing a homogenous polytypic growth. However, due to the intentional off-axis seed or substrate, the normal vector of the exposed surface is misaligned from the normal vector [0001] of the close-packed plane of silicon carbide (SiC). This misalignment acts as another factor contributing to dislocation formation.

To ensure that the grown crystal conforms to the desired polytype, the c-axis stacking sequence must be appropriately exposed. A commonly used technique is to orient the [0001] at an inclination of about 4° (degrees) toward [11 20] of the seed wafer. In the physical vapor transport (PVT) crystal growth, for example, a seed wafer with an off-axis inclination of about 4° is commonly used to facilitate step-flow crystal growth, helping the polytype replication in the growing silicon carbide (SiC) crystal. However, a 4° off-axis silicon carbide (SiC) seed wafer also induces higher defect density during the growth due to the misalignment between exposed surface and the close-packed (0001) plane. In contrast, an on-axis seed wafer, where the exposed surface is well-aligned with the close-packed (0001) plane, which is beneficial for crystal growth with less defects, exhibits no stacking sequence across the surface. Consequently, the on-axis seed wafer fails to guide the incorporation of depositing species into the correct stacking sequence owing to the absence of c-axis stacking sequence information. The polytypes of silicon carbide (SiC) diverse in the subsequent growth stage, also, resulting in several polytypes, which will greatly deteriorate the quality of the as-grown silicon carbide (SiC) crystal.

Furthermore, during the gas-solid reaction of silicon carbide (SiC) crystal growth, minor dislocations in the seed wafer will propagate and extend into the growing crystalline layer during the physical vapor transport (PVT) crystal growth, and thereafter, become the threading dislocations through the crystal. When such a silicon carbide (SiC) single crystal is used for electronic device manufacturing, the corresponding dislocations, acting as failure-prone regions, contribute to a reduction in the yield of the manufactured devices. Using silicon carbide seed wafer with less dislocation density can mitigate the aforesaid issue, but the need of 4° (degrees) off-cutting a thick crystal seed wafer may result in material waste and higher cost.

In summary, while effectively controlling the crystal structure and preventing polytype formation is achievable in an off-axis crystal growth, crystal growth based on an on-axis seed wafer still needs further improvement or modification in the future.

### SUMMARY OF THE INVENTION

The present invention provides a method for micro-patterning the surface of silicon carbide (SiC) seed wafer for single crystal growth. The invention also is a method for micro-patterning a surface of a silicon carbide seed wafer, which is by undergoing a chemical etching process, for single crystal growth.

Specifically, the method involves using a surface micro-patterned silicon carbide (SiC) seed wafer to facilitate single crystal growth. The invention can be applied to an on-axis bulk crystal growth.

The present invention provides a method for producing a surface micro-patterned silicon carbide (SiC) seed wafer, the method comprising: firstly, providing a silicon carbide (SiC) seed wafer; also, providing an alkaline hydroxide aqueous solution; the aqueous solution containing hydroxide ions is filled into an nebulizer to generate a mist of an alkaline hydroxide aqueous solution at room temperature; producing an alkaline hydroxide aqueous mist at room temperature; the silicon carbide (SiC) seed wafer is exposed under a mist of alkaline aqueous solution; the alkaline aqueous solution is condensed onto the surface of the silicon carbide (SiC) seed wafer, and the alkaline aqueous droplets in the sub-micron scale (the droplet size ranges from 100 nanometers to several micrometers, depending on both exposing time to the seed wafer and the volume of the alkaline aqueous solution) undergo self-assembly and deposit onto the surface of the silicon carbide (SiC) seed wafer; after the alkaline aqueous solution droplets are deposited, the seed wafer is subjected to a thermal treatment at 400° C. to 550° C. for about 1 minute to 20 minutes to form the etch pits on the surface of the silicon carbide (SiC) seed wafer; after the etching is completed, deionized water is used to rinse and remove the droplets, leaving orderly etch pits on the surface of the silicon carbide (SiC) seed wafer, wherein the orderly etched pits have fine patterns.

The present invention discloses a method for fabricating a surface micro-patterned silicon carbide (SiC) seed wafer, wherein the method induces an anisotropic reaction through solution etching. Compared to the conventional etching process based on photolithography commonly used in semiconductor manufacturing, this method introduces alkaline solution droplets at room temperature and then followed by a subsequent etching step (a thermal treatment at 400° C. to 550° C.). This process creates etch pits on the surface of silicon carbide (SiC) seed wafer, thereby exposing the stacking sequence along the c-axis of the seed wafer without requiring a tedious photolithography process.

The present invention discloses a method for fabricating a surface micro-patterned silicon carbide (SiC) seed wafer, wherein the method enables the growth of a silicon carbide (SiC) ingot with low dislocation density.

The present invention discloses a method for fabricating a surface micro-patterned silicon carbide (SiC) seed wafer, wherein the method enables the growth of a silicon carbide (SiC) ingot with a controlled crystal structure and prevents the formation of polytypes by-products.

The present invention discloses a method for fabricating a surface micro-patterned silicon carbide (SiC) seed wafer, wherein the method reduces the dislocation density and prevents the formation of other polytypes in the subsequent crystal growth because of the use of an on-axis seed wafer and the exposure of the element stacking sequence along the c-axis.

### BRIEF DESCRIPTION OF THE DRAWINGS

The foregoing aspects and advantages of this invention will become more apparent from the following detailed description, in conjunction with the accompanying drawings, wherein:

FIG. 1 is a flowchart showing the method for micro-patterning a surface of silicon carbide (SiC) seed wafer, as schematically described in the present invention.

FIG. 2A schematically shows an on-axis silicon carbide (SiC) seed wafer in the present invention.

FIG. 2B illustrates the micro-patterned structure on the surface of an on-axis silicon carbide (SiC) seed wafer, as schematically represented in the present invention.

FIG. 3A shows various stacking sequences of silicon carbide (SiC), as schematically shown in the present invention.

FIG. 3B illustrates adatoms and the corresponding schematic diagram in the present invention.

### DESCRIPTION OF THE PREFERRED EMBODIMENT

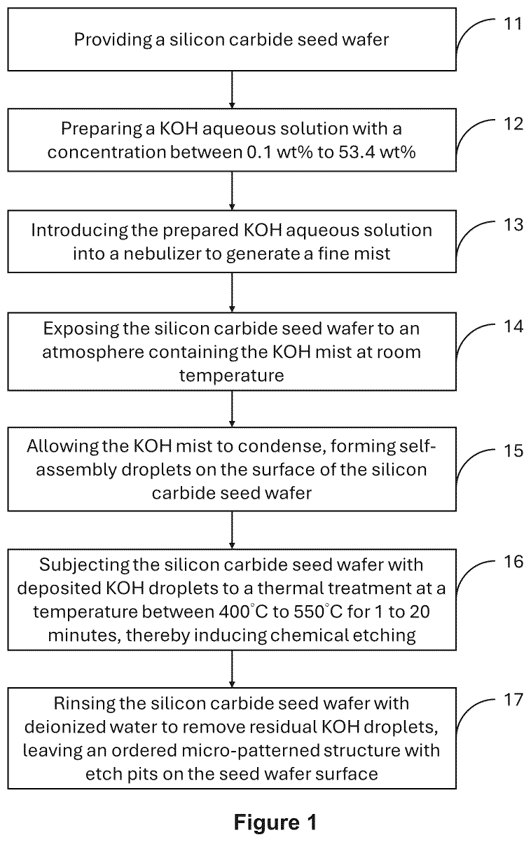

FIG. 1 schematically illustrates a method for fabricating a surface micro-patterned silicon carbide (SiC) seed wafer for single crystal growth, i.e., a method for micro-patterning a surface of a silicon carbide (SiC) seed wafer. Specifically, this method utilizes a micro-patterned silicon carbide (SiC) seed wafer for single crystal growth. In step 11 of FIG. 1, a silicon carbide (SiC) seed wafer, particularly on-axis, is provided. The invention is a method for micro-patterning a surface of a silicon carbide seed wafer, which is by undergoing a chemical etching process, for single crystal growth.

Next, in step 12 of FIG. 1, an alkaline aqueous solution containing hydroxide ions, such as sodium hydroxide aqueous solution (NaOH aqueous solution), barium hydroxide aqueous solution (Ba(OH)2 aqueous solution), calcium hydroxide aqueous solution (Ca(OH)2 aqueous solution), and potassium hydroxide aqueous solution (KOH aqueous solution), which is provided and prepared at room temperature. The concentration of the aforementioned hydroxide aqueous solution ranges from 0.1 wt. % to 53.4 wt. %. Potassium hydroxide (KOH) aqueous solution is selected for the following procedure.

Then, in step 13 of FIG. 1, the prepared potassium hydroxide (KOH) aqueous solution is introduced into a nebulizer to generate a fine mist of an alkaline hydroxide aqueous solution at room temperature. The generated mist exhibits etching capability on a silicon carbide (SiC) seed wafer.

Continuing to step 14 of FIG. 1, the silicon carbide (SiC) seed wafer is exposed to a mist of potassium hydroxide (KOH) aqueous solution. When a silicon carbide (SiC) seed wafer (either on-axis or off-axis) is subjected to the mist generated by a nebulizer, the potassium hydroxide (KOH) solution condenses on the surface of the silicon carbide (SiC) seed wafer. At this stage, the condensed droplets achieve similar sizes due to the interplay between surface tension and surface energy minimization.

Next, in step 15 of FIG. 1, allowing the mist of potassium hydroxide (KOH) aqueous solution to condense onto a surface of silicon carbide (SiC) seed wafer to form a plurality of droplets through a self-assembly process, a plurality of droplets with a controllable size ranging from 100 nanometers to several micrometers is achieved. The potassium hydroxide (KOH) mist forms ordered droplets, which deposit on the surface of the silicon carbide (SiC) seed wafer through a self-assembling effect. The droplet size is controlled by adjusting the seed wafer exposure time to the said mist and the nebulization volume. These condensed droplets naturally arrange into an ordered structure, minimizing thermodynamic free energy. However, the coalescence of nebulized droplets on the seed wafer surface must be prevented, as the coalescence of nebulized droplets leads to the formation of a continuous liquid film instead of discrete droplets.

Continuing to step 16 of FIG. 1, the silicon carbide (SiC) seed wafer with deposited potassium hydroxide (KOH) droplets on the surface undergoes a chemical etching process at a specific temperature. At this stage, the basic droplets deposited on the surface of silicon carbide (SiC) seed wafer are subjected to a thermal treatment between 400° C. to 550° C. for a controlled duration, typically 1 minute to 20 minutes, thereby inducing chemical etching. Wet etching employs chemical solutions to achieve material removal, here is silicon carbide (SiC), through chemical reactions. During this process, the reactants in the solution diffuse through the stagnant boundary layer and reach the seed wafer surface. The products, which are in the liquid or gas phase, diffuse through the boundary layer and then dissolve into the etching solution. Generally, wet etching at 400° C. to 550° C. exhibits highly anisotropic etching selectivity compared to dry etching, which typically processes at a temperature above 1,000° C. That means etchant preferentially etches a specific crystal plane of silicon carbide (SiC) at a higher rate, while the etching rate on the other planes will retain relatively low etching rate. Therefore, when orderly arranged droplets of inorganic basic solution are deposited on the seed wafer surface and subjected to wet etching at a specific temperature (such as 400° C. to 550° C.) for a controlled duration, tiny anisotropic etch pits are formed on the seed wafer surface.

In the final step, step 17 of FIG. 1, deionized water is used to rinse away the condensed droplets with strong basicity, i.e., the condensed potassium hydroxide (KOH) droplets, to remove residual potassium hydroxide (KOH) droplets. After rinsing, the surface of the silicon carbide (SiC) seed wafer is left with ordered etch pits, referred to as micro-patterns, leaving an ordered structure with etched pits on the seed wafer surface. These etched pits expose the stacking sequence along the c-axis of silicon carbide (SiC) facilitating subsequent crystal growth. The desired polytypes can then be grown on the micro-patterned seed wafer, particularly on a seed wafer without off-axis requirement.

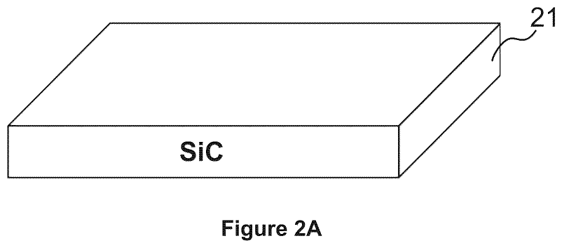

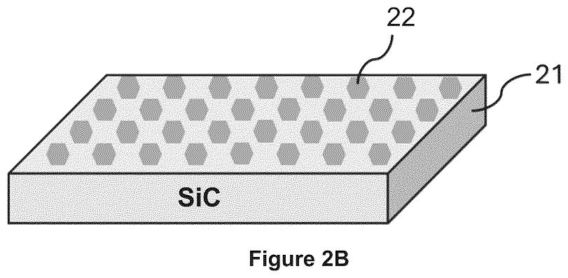

FIG. 2A illustrates a silicon carbide (SiC) seed wafer which can be used as a starting seed for bulk crystal growth in the present invention. FIG. 2B shows a surface micro-patterning structure of a silicon carbide (SiC) seed wafer, wherein a micro-patterned structure 22 is formed on the surface of the silicon carbide (SiC) seed wafer 21.

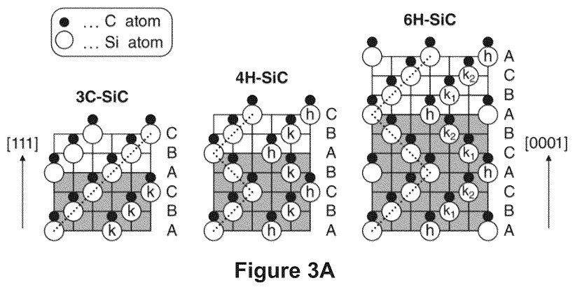

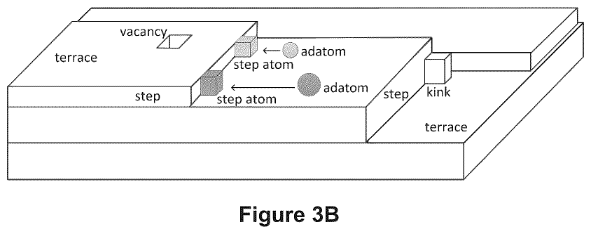

The present invention provides a method for surface micro-patterning an on-axis silicon carbide (SiC) seed wafer, specifically a method for surface micro-patterning silicon carbide (SiC) seed wafer for single crystal growth. This invention enables crystal growth on an exposed surface aligned with the close-packed plane, which effectively reduces dislocation density due to the growth on the close-packed plane of the seed wafer. The micro-patterns on the seed wafer surface reveal the stacking sequence along the c-axis of the seed wafer polytype, helping the replication of seed wafer polytype for the following species deposition, avoiding the formation of undesired polytypes. Notably, silicon carbide (SiC) exhibits hundreds of polytypes. The most practical polytypes, including cubic polytype of 3C, which is 3C-phase silicon carbide, hexagonal polytypes of 4H, which is 4H-phase silicon carbide, and 6H, which is 6H-phase silicon carbide, for semiconductor applications are illustrated with their corresponding stacking sequence in FIG. 3A, FIG. 3A shows various stacking sequence of silicon carbide (SiC), as schematically shown in the present invention.

In FIG. 3A, the black solid circles represent carbon (C) atoms, and the open circles represent silicon (Si) atoms. FIG. 3B also illustrates the stacking sequences for silicon carbide polytypes of 3C, which is 3C-phase silicon carbide, 4H, which is 4H-phase silicon carbide, and 6H, which is 6H-phase silicon carbide. A pair of silicon atom with carbon atom can be considered as a basis, which arranges into a lattice to form silicon carbide polytypes such as 3C, which is 3C-phase silicon carbide, 4H, which is 4H-phase silicon carbide, and 6H, which is 6H-phase silicon carbide. Herein, the abbreviation of C denotes a cubic lattice and H denotes hexagonal lattice. The numerical prefix indicates the repeating unit of the basis within the polytype structure. For instance, 3C describes a cubic polytype with a three-layered repeating basis (ABCABC). Whereas 4H and 6H, they elucidate polytypes of hexagonal polytypes with either a four-layer (ABCBABCB) or six-layer (ABCACBABCACB) repeating basis, respectively.

The present invention provides a method for surface micro-patterning a silicon carbide (SiC) seed wafer, specifically a method for surface micro-patterning a silicon carbide (SiC) seed wafer for single crystal growth. This method is based on the silicon carbide seed wafer, and in subsequent development, the advantages of the present invention are as follows:

The present invention enables the growth of a silicon carbide (SiC) ingot with low defect density. The present invention facilitates the growth of silicon carbide (SiC) ingot on a silicon carbide (SiC) seed wafer (especially on an on-axis silicon carbide (SiC) seed wafer) without forming the undesired polytypes. Thus, this invention shows an advantage of effectively reducing defect density by growing single crystals on an on-axis silicon carbide (SiC) seed wafer. Moreover, the invention assists in controlling polytype formation during crystal growth.

In summary, the present invention discloses a method for facilitating single crystal growth on a silicon carbide (SiC) seed wafer by preparing a micro-patterned structure on a surface of a silicon carbide (SiC) seed wafer. The deposition mechanism of adatoms is governed by the mean free path of reactants, which is highly dependent on processing temperature and free energy. Additionally, the free energy hierarchy of adatoms follows the order: G_{vacancy}<Gₖᵢₙₖ<Gₛₜₑₚ<G_{terrace}, where G_{vacancy} means free energy of an adatom at vacancy, Gₖᵢₙₖ indicates free energy of an adatom at kink site, Gₛₜₑₚ implies free energy of an adatom at step edge, and G_{terrace} depicts an adatom at terrace sites. In other words, adatoms preferentially occupy vacancies, kinks, and steps, rather than terrace sites, as shown in FIG. 3B. At step edge, adatoms incorporate into the step structure and following the same stacking sequence as the seed wafer polytype. However, adatoms on terrace sites show thermodynamic instability, leading to the formation of the metastable 3C polytype. Due to the absence of step structures, it is challenging for an on-axis silicon carbide (SiC) seed wafer to confine adatoms to an appropriate position. Therefore, replicating the same stacking sequence of the seed wafer polytype becomes difficult. The micro-patterned structure addresses this issue by producing a step-like architecture and, provide c-axis stacking sequence information to guide adatoms incorporation into the same polytype as the seed wafer. The disclosure of c-axis stacking sequence is critical for controlling silicon carbide (SiC) crystal growth. If the stacking sequence information along the c-axis is not revealed, the adatoms cannot recognize the stacking sequence and can only interact with exposed carbon or silicon atoms at the surface, corresponding to the (0001̅) carbon plane or (0001) silicon plane, respectively.

That results in the formation of thermodynamically unstable polytypes. Since silicon carbide (SiC) has more than 100 polytypes, each of them exhibits distinct physical properties. Therefore, effectively controlling the polytypes of silicon carbide (SiC) is essential for its further application in advanced semiconductor technology.

Furthermore, the present invention establishes the fundamental principles of a surface micro-patterning method of a silicon carbide (SiC) seed wafer. Due to the interplay between surface tension and surface energy minimization, small potassium hydroxide (KOH) droplets can be well arranged on the seed wafer surface. The desired droplet size is controlled by preventing droplet coalescence, ensuring uniform distribution. Therefore, this unique condensation phenomenon enables the formation of an ordered pattern with controllable size on the silicon carbide (SiC) seed wafer.

Next, the silicon carbide (SiC) seed wafer is subjected to a specific temperature, which ranges from 400° C. to 550° C. That temperature allows the deposited potassium hydroxide (KOH) droplets on the surface to etch the silicon carbide (SiC) seed wafer (especially for on-axis silicon carbide (SiC)) and to form ordered etch pits. These ordered etch pits expose the corresponding stacking sequence of polytypes in the microstructure, also, guide the deposition of adatoms to the appropriate positions. Consequently, the micro-patterned surface facilitates the adatoms to deposit at appropriate sites, and, enabling them to self-arrange based on the stacking sequence of the silicon carbide (SiC) seed wafer.

In summary, a method of micro-patterning a surface of a silicon carbide (SiC) seed wafer comprises the followings: firstly, a silicon carbide (SiC) seed wafer is provided; an alkaline aqueous solution containing hydroxide ions into an nebulizer is prepared; a prepared alkaline aqueous solution containing hydroxide ions is introduced to generate a fine mist of the alkaline aqueous solution containing hydroxide ions at a room temperature ; the silicon carbide (SiC) seed wafer is exposed to the fine mist of the alkaline aqueous solution containing hydroxide ions; the fine mist of the alkaline aqueous solution containing hydroxide ions is allowed to condense onto a surface of silicon carbide (SiC) seed wafer to form a plurality of droplets through a self-assembly process; the silicon carbide (SiC) seed wafer with a plurality of condensed droplets is subjected to a thermal treatment at a temperature between 400° C. to 550° C. for a controlled duration for 1 minute to 20 minutes, thereby chemical etching is induced; and the silicon carbide (SiC) seed wafer is rinsed by deionized water, a plurality of residual droplets is removed and a plurality of orderly arranged etch pits is left on the silicon carbide (SiC) seed wafer, leaving the orderly micro-patterned structure on the silicon carbide (SiC) seed wafer.

It will be appreciated that various modifications and adaptations may be made by those skilled in the art without departing from the scope and spirit of this invention. Accordingly, the scope of the appended claims is not limited to the specific embodiments described herein but, shall be construed to encompass all the features of patentable novelty inherent in the present invention, including all equivalents that would be recognized by those skilled in the art to which this invention pertains.

What is claimed is:

1. A method for micro-patterning a silicon carbide seed wafer, comprising:
providing a silicon carbide seed wafer;
preparing an alkaline aqueous solution containing hydroxide ions into an nebulizer;
introducing a prepared alkaline aqueous solution containing hydroxide ions to generate a fine mist of said alkaline aqueous solution containing hydroxide ions at a room temperature;
exposing said silicon carbide seed wafer to said fine mist of said alkaline aqueous solution containing hydroxide ions;
allowing said fine mist of said alkaline aqueous solution containing hydroxide ions to condense onto a surface of silicon carbide seed wafer to form a plurality of droplets through a self-assembly process;
subjecting said silicon carbide seed wafer with a condensed plurality of droplets to a thermal treatment at a temperature between 400° C. to 550° C. for a controlled duration for 1 minute to 20 minutes, thereby inducing chemical etching; and
rinsing said silicon carbide seed wafer with deionized water, removing a plurality of residual droplets and leaving a plurality of orderly arranged etch pits on said silicon carbide seed wafer, said orderly arranged etch pits forming an orderly micro-patterned structure on said silicon carbide seed wafer.

2. The method according to claim 1, wherein said silicon carbide seed wafer comprises 4H-phase silicon carbide.

3. The method according to claim 1, wherein said silicon carbide seed wafer comprises 6H-phase silicon carbide.

4. The method according to claim 1, wherein said silicon carbide seed wafer comprises 3C-phase silicon carbide.

5. The method according to claim 1, wherein said alkaline aqueous solution containing hydroxide ions is selected from the group consisting of calcium hydroxide, barium hydroxide, sodium hydroxide, and potassium hydroxide.

6. The method according to claim 1, wherein said alkaline aqueous solution containing hydroxide ions comprises an aqueous solution with a concentration ranging from 0.1 wt. % and 53.4 wt. %.

7. A method for micro-patterning a surface of a silicon carbide seed wafer by undergoing a chemical etching process, comprising:
providing a silicon carbide seed wafer;
preparing an alkaline aqueous solution containing hydroxide ions into an nebulizer;
introducing a prepared alkaline aqueous solution containing hydroxide ions to generate a fine mist of said alkaline aqueous solution containing hydroxide ions at a room temperature;
exposing said silicon carbide seed wafer to said fine mist of said alkaline aqueous solution containing hydroxide ions;
allowing said fine mist of said alkaline aqueous solution containing hydroxide ions to condense onto a surface of silicon carbide seed wafer to form a plurality of droplets through a self-assembly process;
subjecting said silicon carbide seed wafer with a condensed plurality of droplets to a thermal treatment at a temperature between 400° C. to 550° C. for a controlled duration for 1 minute to 20 minutes, thereby inducing chemical etching; and
rinsing said silicon carbide seed wafer with deionized water, removing a plurality of residual droplets and leaving a plurality of orderly arranged etch pits on said silicon carbide seed wafer, said orderly arranged etch pits forming an orderly micro-patterned structure on said silicon carbide seed wafer.

8. The method according to claim 7, wherein said silicon carbide seed wafer comprises 4H-phase silicon carbide.

9. The method according to claim 7, wherein said silicon carbide seed wafer comprises 6H-phase silicon carbide.

10. The method according to claim 7, wherein said silicon carbide seed wafer comprises 3C-phase silicon carbide.

11. The method according to claim 7, wherein said alkaline aqueous solution containing hydroxide ions is selected from the group consisting of calcium hydroxide, barium hydroxide, sodium hydroxide, and potassium hydroxide.

12. The method according to claim 7, wherein said alkaline aqueous solution containing hydroxide ions comprises an aqueous solution with a concentration ranging from 0.1 wt. % and 53.4 wt. %.
